(19) United States
(12) Patent Application Publication
(10) Pub. No.: US 2013/0335907 A1
(43) Pub. Date: Dec. 19, 2013

(54) TRAY AND CHASSIS BLADE SERVER ARCHITECTURE

(71) Applicants: Mark Shaw, Sammamish, WA (US); Matthew Allen Faist, El Dorado Hills, CA (US); Eric C. Peterson, Woodinville, WA (US); Harry Raymond Rogers, Bellevue, WA (US); Badriddine Khessib, Redmond, WA (US); Kushagra Virendrakumar Vaid, Sammamish, WA (US)

(72) Inventors: Mark Shaw, Sammamish, WA (US); Matthew Allen Faist, El Dorado Hills, CA (US); Eric C. Peterson, Woodinville, WA (US); Harry Raymond Rogers, Bellevue, WA (US); Badriddine Khessib, Redmond, WA (US); Kushagra Virendrakumar Vaid, Sammamish, WA (US)

(73) Assignee: Microsoft Corporation, Redmond, WA (US)

(21) Appl. No.: 13/495,520

(22) Filed: Jun. 13, 2012

(51) Int. Cl. H05K 7/16; G06F 1/16

(52) U.S. Cl. 361/679.31; 361/679.02; 361/727

(57) ABSTRACT

In computing scenarios involving an aggregation of multiple computational units into a server or computer set, many architectures may be devised to provide physical storage and logical aggregation of the computational units. Presented herein are variations of one such architecture, comprising a chassis having a set of slots, into which may be inserted a tray storing the computational units of one or more blades. Respective trays and chassis slots comprise a power connector and a network connector that are positioned to connect directly (i.e., without a cable or manual interaction) when a tray is inserted into a slot. The chassis stores a set of power supplies, and may connect each blade with a power supply, optionally providing power routing and failover capabilities. The chassis may also provide a management component that connects to and provides management capabilities of the blades of the trays, power supplies, and climate regulating components.

### BACKGROUND

Within the field of computing, many scenarios involve a multi-blade computational unit architecture comprising a support structure configured to store a set of modular computing units. As a first example, a rack server may comprise a set of racks, each sized to hold a computational unit, such as a cased or caseless mainboard including a processor, memory, a power supply, and one or more storage devices, network adapters, and other expansion cards. The mainboard may include a power supply having a power inlet (usually positioned toward the back of the unit) that may be attached to a power outlet of the rack via a power cable, and a network port that may be attached to a network port of the rack using a network cable. As a second example, a blade server may comprise a set of slots, wherein a structural unit may comprise a set of parallel slots respectively configured to receive a computational unit of a “blade” form factor (e.g., a thin, substantially planar array of computational components). The enclosure may therefore store a horizontal or vertical stack of blades, each having an array of components, such as a processor, memory, a storage device, and a power supply, and may provide other services (such as power and network access) through cable attachments to various ports and outlets provided in the enclosure.

In these and other examples, the computational units comprising the server may be managed in various ways. For example, an individual computational unit may be removed from the rack or enclosure and attached to an external set of input and output devices to interact with an operating system and examine or alter the configuration of the computational unit. Alternatively, the individual computational units may enable external interaction; e.g., a terminal services solution may enable a user to interact with the operating system of a computational unit within a shell presented on a second device, and a remote management daemon may provide information about the configuration and status of a computational unit for presentation on a second device. In these and other scenarios, users may query and administer respective computational units of the multi-blade computational unit.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

Some architectural models and management interfaces for multi-blade computational units may present some or all of several disadvantages. As a first example, such systems often utilize cabling to connect the power, network, and other components of a computational unit to the respective sources of such services. While the use of standardized cabling may present broad compatibility for such connections, the cables depend on manual connection to the inlets of the unit; may represent a point of failure; and may clutter the confines of the rack or enclosure that interferes with airflow. As a second example, a rack or blade enclosure may provide slots or spaces for respective computational units, but may only permit a narrow and inflexible range of form factors (e.g., the slots of a blade server may only accommodate computational units of a 1 U size), and/or may not mitigate a misaligned addition of a computational unit that potentially damages nearby computational units and components in the rack or enclosure. As a third example, a rack or blade enclosure may store and provide supporting services for a set of individual computational units, but may provide little or no integration or synergy of the individual computational units; e.g., a rack may enable a set of computational units to operate independently, but may not particularly facilitate the interoperation or management of the array of computational units.

Presented herein are configurations of a multi-blade computational unit architecture involving a chassis comprising a number of slots respectively configured to support an insertable tray hosting one or more blades of the server comprising a set of blade components. The chassis and blade provides power and network connectors that are positioned to couple upon insertion of a tray into a slot of the chassis, thus avoiding the inclusion of cables and the manual manipulation thereof. Additionally, the chassis may accept blades of various types (e.g., a processing blade comprising data processing resources; a storage blade comprising nonvolatile storage components; a network switch blade providing network switching capabilities for other blades; and a mixed blade providing a combination of these types of components). Further, the chassis may enable the integration of the blades, e.g., by including interconnections between processing blades and storage blades, and/or by including a management interface that enables the addition, enumeration, exploration, and configuration of the blades. These and other features are achievable through the tray and chassis architecture provided herein.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is an illustration of an exemplary scenario featuring a rack configured to store computational units of a multi-blade computational unit.

FIG. 2 is an illustration of an exemplary tray configured to store a blade of a multi-blade computational unit according to the techniques presented herein.

FIG. 3 is an illustration of an exemplary chassis configured to support a set of trays of a multi-blade computational unit according to the techniques presented herein.

FIG. 4 is an illustration of an exemplary scenario featuring a tray and chassis combination with respective blades connected to the chassis by a unified connector.

FIG. 5 is an illustration of an exemplary scenario featuring various blade types comprising variable sets of blade components.

FIG. 6 is an illustration of an exemplary scenario featuring chassis storing variable sets of blades and further comprising a chassis management component configured to manage the blades, chassis power supplies, and chassis cooling components.

FIG. 7 is an illustration of an exemplary computing environment wherein one or more of the provisions set forth herein may be implemented.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, structures and devices are shown in block diagram form in order to facilitate describing the claimed subject matter.

### A. INTRODUCTION

Within the field of computing, many scenarios involve a server comprising a plurality of computational units. As a first example, the server may comprise a set of independently operable computers configured to intercommunicate to achieve a task in a cooperative manner, such as a server farm or a peer-to-peer processing network. As a second example, the server may comprise a set of computational units, such as processors or storage arrays, that are coordinated by a coordinating module, such as in a symmetric multiprocessor (SMP) model. As a third example, the server may comprise a set of computational components that may autonomously process data, but that share resources such as input/output components, such as a rack server comprising a set of mainboards and a switch configured to enable user interaction with a single mainboard. In these scenarios, the server may comprise a set of resources to provide various functionality (e.g., power supplies that supply power to the computational units; climate components (e.g., fans, heatsinks, air conditioners, heaters, humidifiers, and dehumidifiers) that regulate the temperature, humidity, and/or airflow of the components; communication components, such as wired and/or wireless network adapters and network switches; user input components, such as keyboards, mice, microphones, and cameras; user output components, such as displays, speakers, and printers; and physical protection, such as enclosures and physical locks. In various scenarios, each unit may have a dedicated resource (e.g., each computer may have a separate enclosure and dedicated input/output devices), or a resource may be shared among two or more units (e.g., in a rack server, each computational unit may have a dedicated processor and volatile storage, and may provide a pool of nonvolatile storage, such as a redundant array of inexpensive disks (RAID) unit, that is shared by all of the units for nonvolatile storage). Additionally, in different server scenarios, the degree of interoperation of the units may vary from complete independence (e.g., units that provide independent functions and that seldom intercommunicate, or are even isolated from each other; units that operate independently but intercommunicate to achieve a particular task; or units that are incapable of independent operation without direction from a management module).

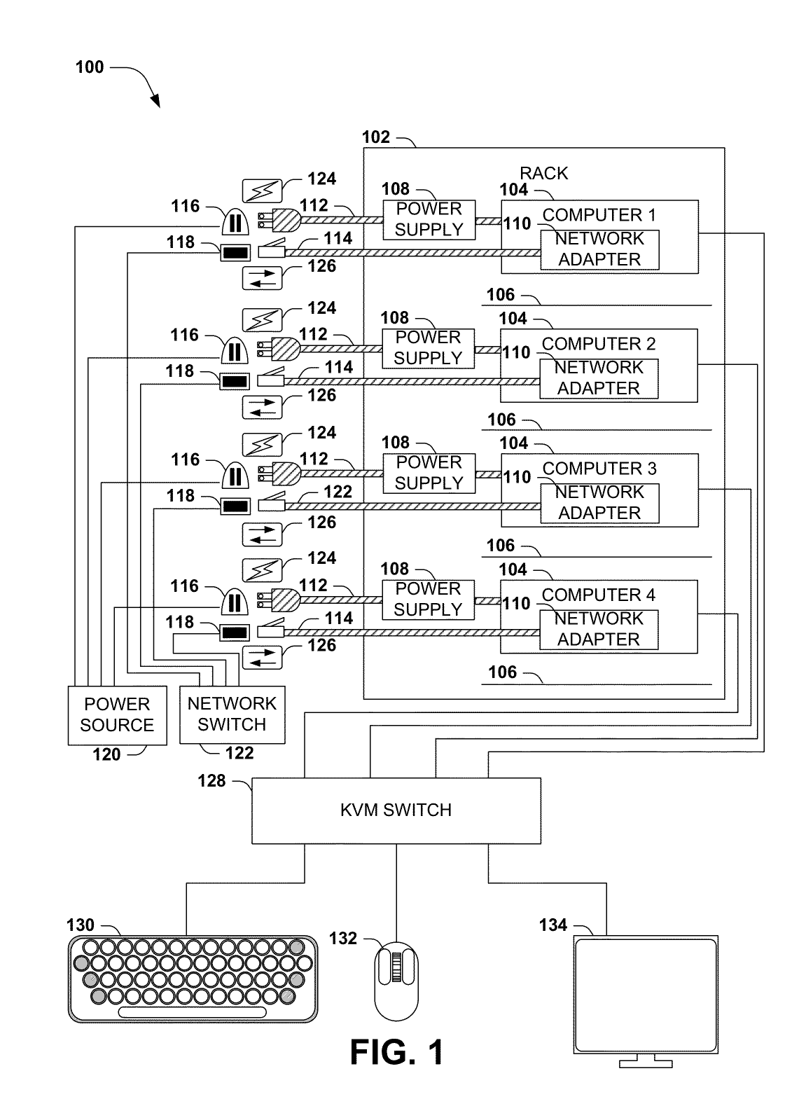

FIG. 1 presents an illustration of an exemplary scenario 100 featuring a multi-unit rack server, comprising a rack 102 configured to store a set of computers 104 on a vertical array of shelves 106. In this exemplary scenario 100, each computer 104 is connected to a power supply 108 stored on the shelf 106 and attached to the computer 104 via a power cable 112, and comprises an enclosure featuring a complete set of computational components, such as one or more processors, volatile and nonvolatile storage, and a network adapter 110. In addition to providing a physical structure and organization of the computers 104, the rack 102 presents various components that may supplement the computers 104 and the interoperation thereof. As a first example, the rack 102 comprises a set of standard power outlets 116, into which a power cable 112 of the power supply 108 may be inserted to receive power 124 from a power source 120, thus enabling any computer 104 to be powered through its ordinary power supply 108. As a second example, the rack 102 comprises a set of network ports 118 (e.g., an RJ45 or RJ11 jack), into which one end of a standard network cable 114 (e.g., a CAT5 or CAT6 Ethernet cable) may be inserted to connect to a network adapter 110. The network ports 118 may be connected to a network switch 122 (e.g., embedded in the rack 102, or external to the rack 102 and connected to network ports 118 via a set of cables) to provide network connectivity 124 to the network adapters 110 of the computers 104. As a third example, the rack 102 may include a keyboard/video/mouse (“KVM”) switch 128, to which are connected a keyboard 130, mouse 132, and video display 134, as well as one or more connections with respective computers 104 (e.g., a High Definition Multimedia Interface (HDMI) cable or a Universal Serial Bus (USB) cable). The switch 128 may present a toggle that enables the connection of these devices to any computer 104 positioned in the rack 102. By presenting these components in addition to the physical structure and organization of the shelves 106, the rack 102 therefore supports the functioning, interoperation, and resource-sharing of the computers 104 stored therein.

However, the rack 102 in the exemplary scenario 100 of FIG. 1, and many similar devices, may present some limitations. As a first example, in many such scenarios, the ports of a computer 104 (such as the ports for the power adapter 108 and the network adapter 110) are positioned at the back of the computer 104, and accessing these ports to the power outlet 116 and the network port 118 of the rack 102 may be difficult (e.g., the user may have difficulty seeing and/or reaching the ports behind the computer 104). As a second example, the power cable 112 and the network cable 114 consume space; may involve an extra expense of resources; and/or may represent an additional point of failure. As a third example, the rack 102 may provide only limited integration of the computers 104 through the KVM switch 128; e.g., the rack 102 provides limited capabilities for enumerating, querying, and configuring the computers 104 within the rack 102, and provides no capabilities for managing any of the other components of the rack 102, such as the power supplies 108, the power source 120, and the network switch 122. As a fourth example, the rack 102 may only support computers 104 of a particular type, and may provide limited or no capabilities to support other types of computational resources, such as a computational unit comprising only nonvolatile storage (e.g., a Redundant Array of Inexpensive Disks (RAID) device, or a unit having only processing components and lacking nonvolatile storage). As a fifth example, the shelves 106 may enable only limited height adjustments, and may therefore fail to accommodate a computer 104 with extra height and/or may present excess space around a computer 104, thus presenting a space inefficiency. These and other disadvantages may result from racks 102 and other enclosures of multi-blade computational units.

### B. PRESENTED TECHNIQUES

Presented herein are architectures for multi-blade computational units that enable various advantages with respect to other architectures, including the rack 102 in the exemplary scenario 100 of FIG. 1. The architectures presented herein comprise a chassis that presents a plurality of slots, each configured to receive a tray that stores and organizes the components of a blade. The components of a blade may be selected for particular blade type, such as a processing blade type (e.g., one or more processors and volatile memory), a storage blade type (e.g., one or more nonvolatile storage devices and a nonvolatile storage array controller), and a mixed blade type (e.g., processors, volatile memory, and at least one nonvolatile memory device). The tray also includes a tray power connector and a tray network connector, which may be configured to couple respectively with a chassis power connector and a chassis network connector positioned within the slot, and through which power 124 and network connectivity 126 may be provided. Moreover, the connectors may be positioned to couple directly upon insertion of a tray into the slot, rather than using a cable. The tray also includes one or more tray guides that are configured to couple with chassis guides within a slot of the chassis. The guides may enable the insertion of the tray in position to couple the connectors without manual intervention, even correcting a small amount of misalignment of the connectors, and may block incorrect insertion of the tray in a manner that may otherwise fail to achieve connection and/or may damage the connectors.

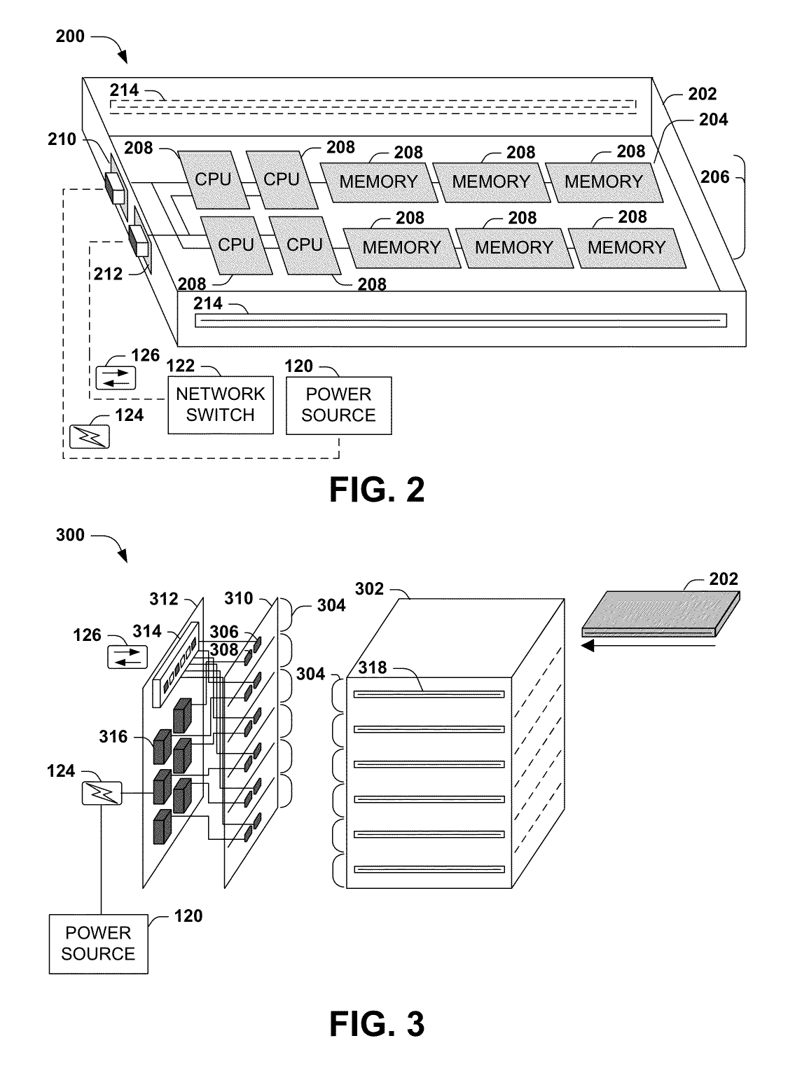

FIG. 2 is an illustration of an exemplary scenario 200 featuring a tray 202 designed according to the techniques presented herein for use with a chassis. This exemplary tray 202 comprises a tray base 204, such as a bottom surface of the tray 202, that is configured to support a set of blade components 208 comprising a blade 206, such as a mainboard connecting a set of processors and a set of volatile memory components. The tray 202 also comprises a tray power connector 210, which is configured to couple with at least one blade component 208 of the blade 206 and provide power for the blade 206, and a tray network connector 212, which is configured to couple with at least one blade component 208 of the blade 206 and provide network connectivity for the blade 206. The tray power connector 210 and the tray network connector 212 are also positioned to, upon insertion of the tray 202 into a slot of the chassis, couple directly with (respectively) a chassis power connector and a chassis network connector positioned within the slot of the chassis, rather than involving a cable connecting the tray connectors with the corresponding chassis connectors. The tray 202 also comprises a set of tray guide 214, such as rails positioned along each lateral wall of the tray 202, that, upon insertion of the tray 202 into a slot of the chassis, respectively couple with a chassis guide of the chassis (e.g., a lateral groove along the interior side wall of each slot) to guide the insertion of the tray 202 to couple the tray power connector 210 with the chassis power connector and the tray network connector 212 with the chassis network connector, and that mitigate incorrect insertion of the tray 202.

FIG. 3 presents an illustration of an exemplary scenario 300 featuring an exemplary chassis 302 configured to store a multi-blade computational unit, where each blade 206 is stored within a tray 202. The chassis 302 comprises a set of slots 304, each configured to accommodate a tray 202 storing one or more blades 206 of the multi-blade computational unit. The chassis 302 also comprises at least one chassis power supply 316 that is configured to provide power 124 from a power source 120, and at least one chassis network source connector 314 configured to provide network connectivity 126 (e.g., a network port, network hub, network switch 128, or network router that may be connected to a telephone, Ethernet, or optical communication uplink). The chassis 302 also comprises at least two substantially parallel slots 304 that are respectively configured to host a tray 202 storing at least one blade 206. The respective slots 304 of the chassis 302 comprise at least one chassis power connector 306, which is configured to receive power from a chassis power supply 316, and which is positioned to, upon insertion of a tray 202 into the slot 304, couple directly with a tray power connector 210 of the tray 202 (rather than involving a power cable 112) to provide power 124 to a blade 206 of the tray 202. The respective slots 304 of the chassis 302 also comprise at least one chassis network connector 308, which is configured to communicate with the chassis network source connector 314, and which is positioned to, upon insertion of the tray 202 into the slot 304, couple directly with a tray network connector 212 of the tray 202 (rather than involving a network cable) to provide network connectivity 126 to a blade 206 of the tray 202. The chassis power connectors 306 and chassis network connectors 308 may be provided on a first chassis portion 310 (e.g., a back wall of the chassis 302), and the chassis power supplies 316 may be provided on a second chassis portion 312 (e.g., a side wall of the chassis 302). Moreover, the first chassis portion 310 and/or second chassis portion 312 may be modular and removable to enable service to the components positioned thereupon. Additionally, the respective slots 304 of the chassis 302 also comprise one or more chassis guides 318, such as grooves provided along the interior side walls of the slot 304, that are configured to couple with a tray guide 214 of the tray 202 and, upon insertion of the tray 202 into the slot, guide the insertion of the tray 202 to couple the chassis power connector 306 directly with the tray power connector 210 and the chassis network connector 308 directly with the tray network connector 212.

The compatible architectures presented herein for a tray 202 and chassis 302, such as those respectively depicted in the exemplary scenarios 300, 400 of FIGS. 2 and 3, may present various advantages as compared with other architectures, such as the exemplary rack 102 in the exemplary scenario 100 of FIG. 1. As a first example, an insertable tray architecture may enable easy insertion and removal of a blade 206 from the multi-blade computational unit, particularly facilitated by the coupling of tray guides 214 with chassis guides 318 within each slot 304, as compared with the disposition of a computer 104 on a shelf 106 of the rack 102. As a second example, the selection and positioning of tray power connectors 210 and tray network connectors 212 for direct connection with a chassis power connector 306 and chassis network connector 308 within a slot 304 of the chassis 302, reduces the cabling establishing such connections in the rack 102, thereby reducing the cost, space consumption, and potential failure of power cables 112 and network cables 114 within the rack 102, as well as potentially difficult manual manipulation and connection of such cabling in a difficult-to-see location near the back of each computer 104. As a third example, the heights of respective slots 304 may be closely matched with the height of a tray 202. Alternatively, a tray 202 may exceed the height of a single slot 304 and extend into one or more additional (vacant) higher slots 304, while still connecting with the chassis power connector 306 and the chassis network connector 308 of the selected slot 304. As a fourth example, the architecture of the chassis 302 may enable additional features, such as the provision of power 124 and/or network connectivity 126 to various types of blades 204; a modular design for respective components of the chassis 302, such as the disposition of the chassis power supplies 316 on a specific wall of the chassis 302 that may enable removal and servicing of the chassis power supplies 316 servicing all of the blades 204; and the inclusion of a chassis management component, such as an additional computer embedded in the chassis 302 that may connect with and provide management capabilities for the trays 202, chassis power supplies 316, and other components of the chassis 302 such as climate regulation components. These and other advantages may be achievable through the tray 202 and chassis 302 architecture presented herein.

### C. VARIATIONS

The architecture presented herein for the tray 202 and the chassis 302 may be implemented with variations in many aspects, and some variations may present additional advantages and/or reduce disadvantages with respect to other variations of these and other architectures and implementations. Moreover, some variations may be implemented in combination, and some combinations may feature additional advantages and/or reduced disadvantages through synergistic cooperation.

C1. Scenarios

A first aspect that may vary among embodiments of these techniques relates to the scenarios wherein such techniques may be utilized. As a first example of this first aspect, the tray and chassis architecture may implement many types of multi-blade computational units, such as file servers, webservers, database servers, and distributive processing servers. As a second example of this first aspect, the blades 204 of the multi-blade computational units may present varying types and degrees of interoperability (e.g., a mutually isolated set of blades 206; an intercommunicating set of independent blades 206 interacting in a peer-to-peer or server-client model; and a tightly coupled set of computational units, such as a symmetric multiprocessing (SMP) server). As a third example of this first aspect, the chassis 304 and trays 202 may be provided together, separately by the same supplier, or separately by different suppliers that confer to provide compatibility thereamong. These and other scenarios may advantageously utilize the tray and chassis architectures presented herein.

C2. Chassis and Tray Design

A second aspect that may vary among embodiments of the techniques presented herein involves the design of the chassis 302 and tray 202.

As a first example of this second aspect, the trays 202 may contain many types of blade components 208. As a first such example, the trays 202 may be user-serviceable, and may permit the addition and removal of blade components 208, e.g., through a snap-type model that enables blade components 208 to be manually “snapped” or depressed onto and/or manually detached from respective portions of a mainboard. Alternatively, respective blades 206 may comprise a distinct unit comprising the blade components 208 (e.g., in a separate sealed or user-serviceable enclosure) that may be included the tray 202 by sliding the distinct blade unit into a blade region of the tray 202. As a second such example, the tray 202 may be manufactured and provided within a fixed enclosure, such that the blade 206 is protected from physical shock and physical intrusion or manipulation. As a third such example, the tray 202 may include two or more blades 206, each comprising a discrete set of blade components 208. On one such embodiment, a tray 202 may be apportioned into at least two tray blade regions, each storing the blade components 208 of a blade 206, and may provide a tray power connector 210 and a tray network connector 212 for each blade 206 within the tray 202. In this manner, multiple blades 206 may be provided in a single tray 202 to increase the number of blades 206 of the multi-blade server stored in the chassis 302.

As a third example of this second aspect, the trays 202 and chassis 302 may utilize many types of directly connecting power and network connectors. For example, a “blind mate” connector design enables the coupling of the connectors on the back of a tray 206 with the corresponding connectors at the back of a slot 304 of the chassis 302 without manual intervention. As an example of such a connector, the respective connectors may comprise magnetic plates of opposing polarity that establish and maintain contact through weak magnetic attraction, and thus pair to transmit an electric signal. Additionally, in some embodiments, the power connectors and network connectors may be combined into a unified connector that provides both power 124 and network connectivity 126 to the blade 206. To this end, a chassis unified connector may be positioned within the slot 304 to be connected with a tray unified connector of the tray 202 in order to provide both power 124 and network connectivity 126 to a blade 206. The connector may also include any other type of communication data (e.g., a Universal Serial Bus (USB) connection, or a Serial Attached SCSI (SAS) bus).

As a fourth example of this second aspect, the trays 202 may be insertable into and removable from the slots 304 of the chassis 302 in many ways. Additionally, many types of tray guides 214 and/or chassis guides 318 may be selected to achieve the guidance of the insertion of the tray 202. As a first such example, the trays 202 may slide into a slot 304, and the tray guide 214 and chassis guide 318 may comprise (respectively or vice versa) a rail and a groove. As a second such example, the tray guide 214 and chassis guide 318 may comprise halves of an interlocking structure, such that, when the tray 202 is properly (manually) positioned within the slot 304, a small amount of physical force causes the tray 202 to snap into place for the power connectors and network connectors to couple, but that resists physical force during a misalignment of the tray 202 to avoid physical damage to the power and network connectors. As a third such example, the slot 304 may comprise a motorized bracket that, upon detecting the presence of a tray 202 in the bracket, moves the tray 202 into the correct position to connect the power connectors and the network connectors.

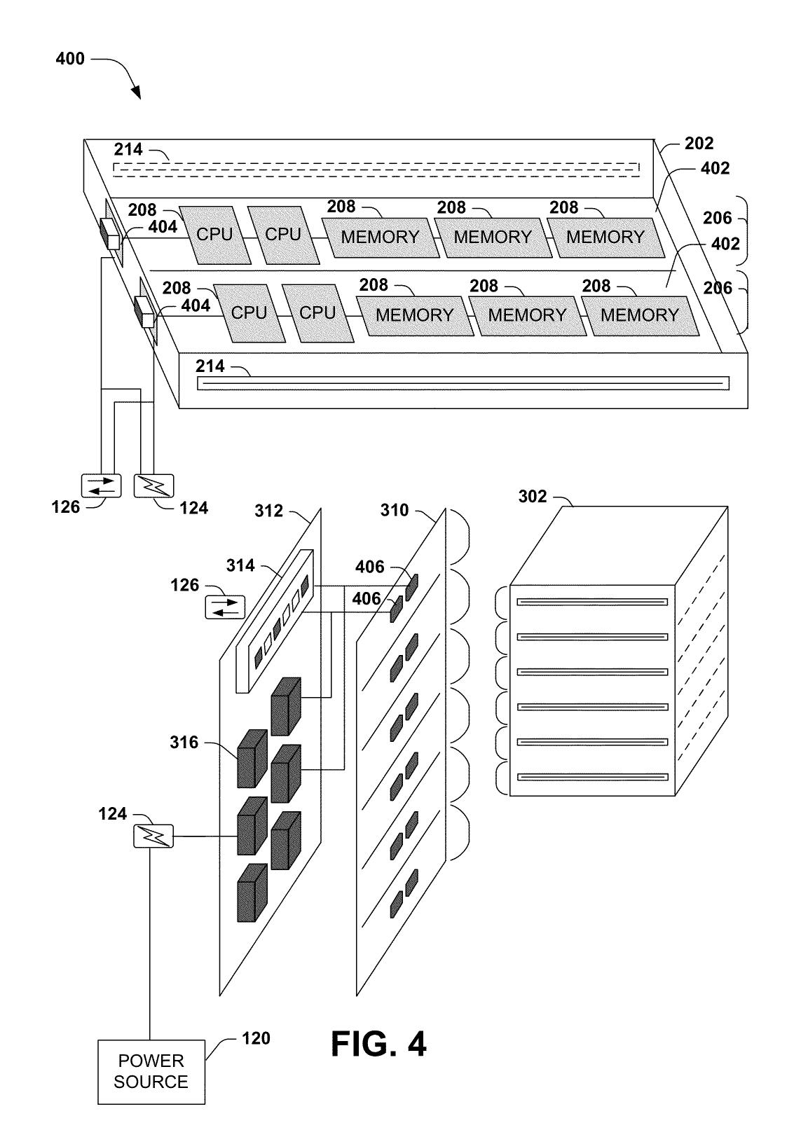

FIG. 4 presents an illustration of an exemplary scenario 400 featuring some of these variations in the design of the tray 202 and chassis 302. In this exemplary scenario 400, a tray 202 is provided to store blade components 208, such as processors and volatile memory components. However, the tray 202 is apportioned into two tray blade regions 402, each comprising the blade components 208 of a blade 206; the tray 202 thus provides two blades 206 for the multi-blade computational units. Additionally, in this exemplary scenario 400, the tray power connector 210 and the tray network connector 212 are combined into a tray unified connector 404 that provides both power 124 and network connectivity 126 to a blade 206. The tray 202 thus includes two tray unified connectors 404, each providing power 124 and network connectivity 126 for one of the blades 206. Correspondingly, each slot 304 of the chassis 302 includes two chassis unified connectors 406, each configured to supply both power 124 from one or more power supplies 316 and network connectivity 126 from a chassis network source connector 314 to one of the two blades 206 that may be stored within a tray 202. As a third example, the tray 202 includes tray guides 214 comprising rails that couple with chassis guides 318, and thus enable a user to slide the tray 202 into the chassis 302 to couple the tray unified connectors 404 of one or both blades 206 with the chassis unified connectors 406 within the slot 304 of the chassis 302. In this manner, the tray 202 and chassis 302 may be configured in a manner incorporating several of the variations presented herein.

C3. Blade Components

A third aspect that may vary among embodiments of these techniques relates to the types of blade components 208 comprising a blade 206 stored in the tray 202.

As a first example of this third aspect, many types of computational units may be included as blade components 208, such as processors, volatile and nonvolatile memory components, display and sound adapters, communications devices such as network adapters, and communications buses. While the tray 202 may be designed to accommodate many types of blade components 208, in some embodiments, the blade components 208 may exceed the standard size of the tray 202. In such cases, the dimensions of the tray 202 may vary; e.g., a tray 202 may be designed having the height of two standard trays 202 to accommodate tall blade components 208, and may occupy two slots 304 of the chassis 302. Alternatively, the tray 202 may omit a top surface, or may include an expandable or removable top surface, to enable the inclusion of taller blade components 208. Similarly, the tray 202 may accommodate blade components 208 that utilize power 124 and/or network connectivity 126 exceeding the resources provided through one tray power connector 210 and/or one tray network connector 212. Accordingly, a tray 202 may enable a blade 206 to connect to and utilize the power 124 and/or network connectivity 126 provided by two or more connectors.

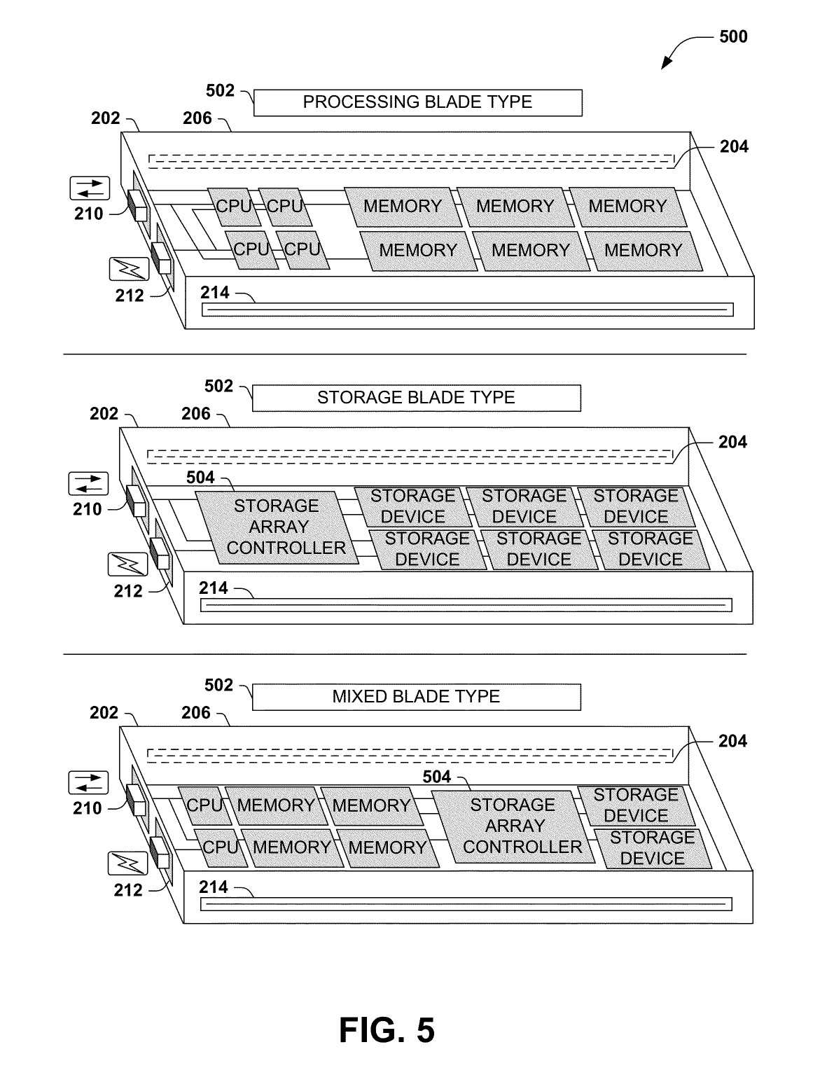

As a second example of this third aspect, a tray 202 may store blade components 208 that together comprise a blade type of a blade 206. FIG. 5 presents an illustration of an exemplary scenario illustrating various blade types 502. As a first such example, a processing blade type 502 may comprise blade components 208 such as microprocessors, field-programmable gate arrays (FPGAs), and volatile memory components providing working memory storage, that together provide processing capabilities for the multi-blade computational units. As a second such example, a storage blade type 502 may comprise blade components 208 such as nonvolatile storage devices (e.g., hard disk drives, solid-state storage devices, and magnetic and/or optical disks), that together provide nonvolatile storage for the multi-blade computational unit. The storage blade type 502 may also include a storage array controller 504 that aggregates two or more storage devices into a storage array with various features, such as increased capacity, increased throughput, increased reliability, and/or versioning, such as may be provided by various configurations of a Redundant Array of Inexpensive Disks (RAID) storage pool. As a third example, a mixed blade type 502 may comprise blade components 208 providing both processing capabilities and storage capabilities. Still further blade types 502 may provide more specialized capabilities (e.g., processing blade types particularly configured to provide database processing, web service, or media encoding or decoding) and/or other capabilities (e.g., a network switch blade type 502 comprising one or more network switches that provide network routing and filtering capabilities for one or more blades 206 stored within the chassis 202). Additionally, a tray 202 may comprise an empty blade type 502. This configuration may be advantageous, e.g., if at least one tray 202 and/or tray blade region 402 is vacant, and if an absence of blade components 208 may create an airflow passage that unbalances climate regulation within the chassis 302. Accordingly, a tray 202 may store one or more airflow block components that physically obstruct airflow in order to maintain airflow balance among the trays 202 of the chassis 302.

In view of the various types of blade types 502 of respective blades 206 that may be presented in respective trays 202, the trays 202 may be configured to communicate a blade type 502 of each stored blade 306 to the chassis 302, and the chassis 302 may be configured to enable an aggregation of blades 206 of different blade types 502 into a multi-blade computational unit. As a first such example, the chassis 302 may detect the different blade types 502 of respective blades 206, and may connect processing blades with storage blades to provide nonvolatile storage for the processing units. As a second such example, the chassis 302 may alternatively facilitate the intercommunication of processing blades to achieve a cooperative task, and/or may isolate intercommunication among processing blades to improve the security of discretely operating processors. As a third such example, the chassis 302 may route network communication for respective processing blades through a network switch provided in a different tray 202. These and other adjustments may be enabled by the interoperation of the trays 202 and the chassis 302 in accordance with the techniques presented herein.

C4. Additional Chassis Components

A fourth aspect that may vary among embodiments of these techniques relates to the inclusion of additional components in the chassis 302 that may facilitate the production of the multi-blade computational unit.

As a first example of this fourth aspect, a chassis 302 may include one or more power supplies 316 to provide power 124 to respective blades 206 within the trays 202. As a first such example, the chassis 302 may connect each blade 206 to one power supply 316. As a second such example, the chassis 302 may aggregate the power 124 provided by several power supplies 316, and may distribute the power 124 to all of the blades 206. This distribution may provide redundancy among the power supplies 316; e.g., the chassis 302 may include at least one extra power supply 316, and may provide failover power routing in the event of a failure of one or more power supplies 316.

As a second example of this fourth aspect, the chassis 302 may include one or more chassis climate regulating components, such as fans, heatsinks, air conditioning units, heaters, humidifiers, and dehumidifiers, that together regulate the climate within the chassis 302 on behalf of the blades 304.

As a third example of this fourth aspect, the chassis 302 may include one or more networking components that, in addition to conveying network connectivity from a network source connector 314 to the tray network connectors 212 through the chassis network connectors 308, provide additional network services. For example, a network switch may be integrated in the chassis 302 (i.e., not within a tray 202, but within the body of the chassis 302) that enables configurable routing of network connectivity 126 to the blades 206 of the trays 202.

As a fourth example of this fourth aspect, the chassis 302 may include a chassis management component that is configured to manage other blades 206 of the multi-blade computational unit, and optionally other components of the chassis 302. The chassis management component may be included within a tray 202 as a set of blade components 208 of a chassis management blade type. Alternatively, the chassis management component may be implemented as a processing component embedded in the chassis 306 and not supported by a tray 202.

As another variation of this fourth example of this fourth aspect, the chassis management component may provide management interactions with respective components through specialized connectors, which may provide a dedicated management channel among the chassis management component and the components of the trays 202 and chassis 302. As a first such example, the chassis management component may comprise a chassis management interface connector, and respective trays 202 may comprise a tray management interface connector, which is configured to couple with a blade management interface connector of at least one blade component 208 of the blade 206, and positioned to couple with the chassis management interface connector upon insertion of the tray 202 into the slot 304 of the chassis 302. As a second such example, respective chassis power supplies 316 may comprise a chassis power supply management interface connector that couples with a chassis power management component connector of the chassis management component. As a third such example, respective chassis climate regulating components may comprise a chassis climate regulating component management connector that couples with a chassis climate regulating component management interface connector of the chassis management component.

As a fifth example of this fourth aspect, the multi-blade computational unit may combine the blades 206 of the chassis 302 with the blades 206 of one or more additional chassis 302 (e.g., multiple chassis 302 stored in the same rack, or chassis 302 stored in other racks). As one such example, multiple chassis 302 may exchange information about the trays 202, blades 206, and blade types 502 presented therein. In order to enable such intercommunication, respective chassis 302 may include a chassis mount connector, which is configured to couple with a rack mount connector of a rack configured to store at least two chassis 302. These and other types of components may be added to extend the capabilities of the chassis 302 by those of ordinary skill in the art in accordance with the techniques presented herein.

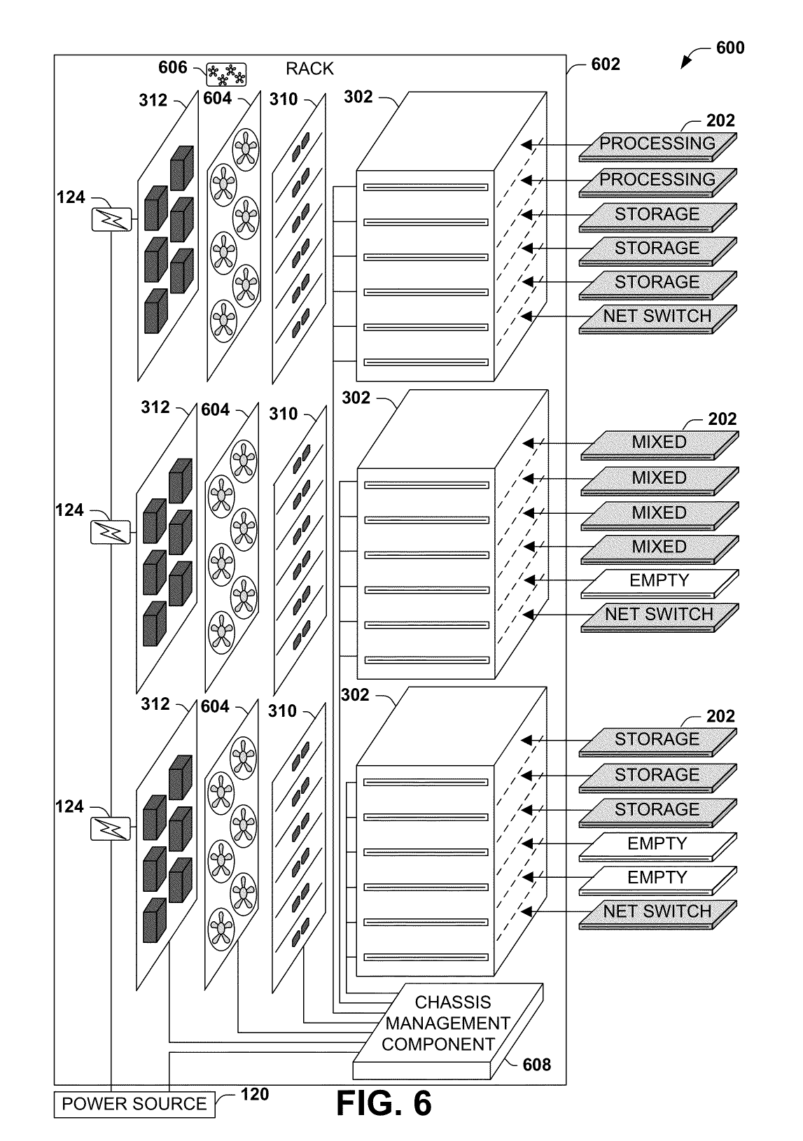

FIG. 6 presents an illustration of an exemplary scenario 600 featuring several variations of this fourth aspect. In this exemplary scenario 600, a rack 602 is provided that is capable of storing at least three chassis 302, each providing six slots 304 respectively configured to host a tray 202 storing the blade components 208 of a blade 206. The blade types 502 of the blades 302 within each chassis 302 may vary, and each chassis 302 may provide a multi-blade computational unit using only the blades 206 within the chassis 302, or may communicate with other chassis 302 to provide a multi-blade computational unit using the combined blades 206 within the trays 202 of multiple chassis 302. Additionally, each chassis 302 may include a first chassis portion 310 presenting the chassis power connectors 306 and chassis network connectors 308 to be connected to the respective connectors of each blade 206 of each tray 202; a second chassis portion 312 presenting a set of power supplies of the chassis 302 and connected to a power source 120; and a third chassis portion 604 presenting a set of climate regulating components (e.g., fans) that provide climate regulation 606. Additionally, the chassis 302 may include (embedded within the chassis 302 rather than as a tray 202) a chassis management component 608, which may be connected to the slots 304 of each chassis 302, the power supplies 312, the power source 102, and the chassis regulating components, and may provide management capabilities such as enumeration, status reports, and configuration. In this manner, the exemplary scenario 600 of FIG. 6 presents several variations of this fourth aspect.

### D. COMPUTING ENVIRONMENT

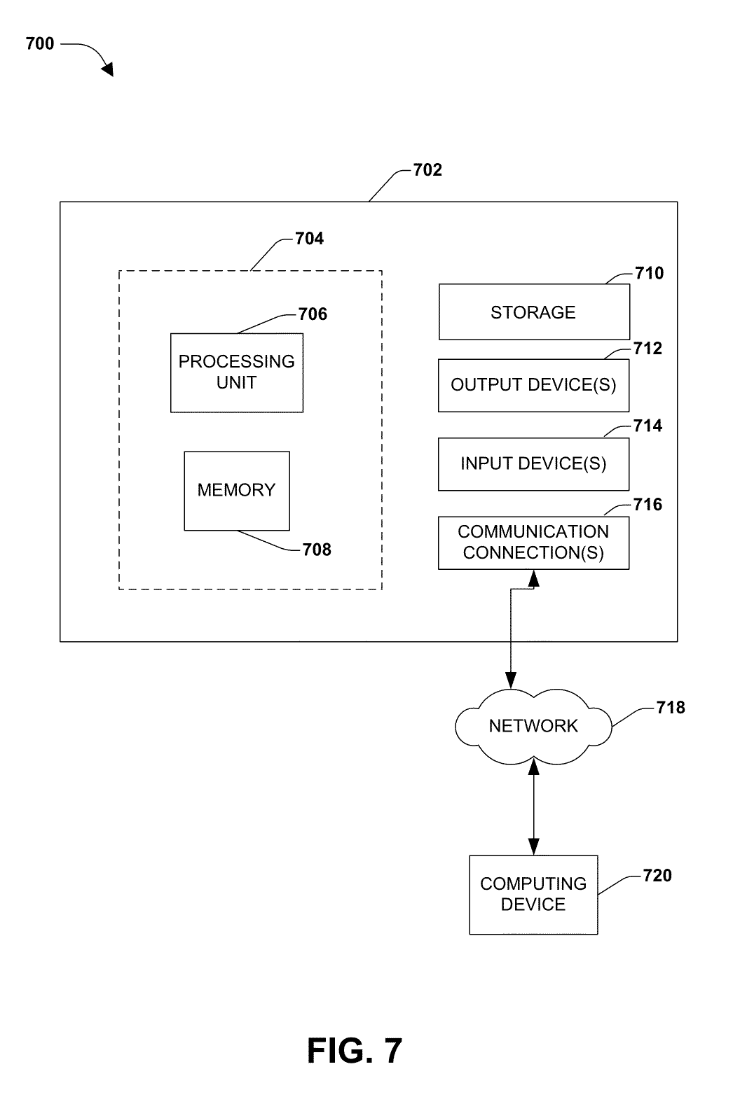

FIG. 7 presents an illustration of an exemplary computing environment within a computing device 702 wherein the techniques presented herein may be implemented. Example computing devices include, but are not limited to, personal computers, server computers, hand-held or laptop devices, mobile devices (such as mobile phones, Personal Digital Assistants (PDAs), media players, and the like), multiprocessor systems, consumer electronics, mini computers, mainframe computers, and distributed computing environments that include any of the above systems or devices.

FIG. 7 illustrates an example of a system 700 comprising a computing device 702 configured to implement one or more embodiments provided herein. In one configuration, the computing device 702 includes at least one processor 706 and at least one memory component 708. Depending on the exact configuration and type of computing device, the memory component 708 may be volatile (such as RAM, for example), non-volatile (such as ROM, flash memory, etc., for example) or an intermediate or hybrid type of memory component. This configuration is illustrated in FIG. 7 by dashed line 704.

In some embodiments, device 702 may include additional features and/or functionality. For example, device 702 may include one or more additional storage components 710, including, but not limited to, a hard disk drive, a solid-state storage device, and/or other removable or non-removable magnetic or optical media. In one embodiment, computer-readable and processor-executable instructions implementing one or more embodiments provided herein are stored in the storage component 710. The storage component 710 may also store other data objects, such as components of an operating system, executable binaries comprising one or more applications, programming libraries (e.g., application programming interfaces (APIs), media objects, and documentation. The computer-readable instructions may be loaded in the memory component 708 for execution by the processor 706.

The computing device 702 may also include one or more communication components 716 that allows the computing device 702 to communicate with other devices. The one or more communication components 716 may comprise (e.g.) a modem, a Network Interface Card (NIC), a radiofrequency transmitter/receiver, an infrared port, and a universal serial bus (USB) USB connection. Such communication components 716 may comprise a wired connection (connecting to a network through a physical cord, cable, or wire) or a wireless connection (communicating wirelessly with a networking device, such as through visible light, infrared, or one or more radiofrequencies.

The computing device 702 may include one or more input components 714, such as keyboard, mouse, pen, voice input device, touch input device, infrared cameras, or video input devices, and/or one or more output components 712, such as one or more displays, speakers, and printers. The input components 714 and/or output components 712 may be connected to the computing device 702 via a wired connection, a wireless connection, or any combination thereof. In one embodiment, an input component 714 or an output component 712 from another computing device may be used as input components 714 and/or output components 712 for the computing device 702.

The components of the computing device 702 may be connected by various interconnects, such as a bus. Such interconnects may include a Peripheral Component Interconnect (PCI), such as PCI Express, a Universal Serial Bus (USB), firewire (IEEE 794), an optical bus structure, and the like. In another embodiment, components of the computing device 702 may be interconnected by a network. For example, the memory component 708 may be comprised of multiple physical memory units located in different physical locations interconnected by a network.

Those skilled in the art will realize that storage devices utilized to store computer readable instructions may be distributed across a network. For example, a computing device 720 accessible via a network 718 may store computer readable instructions to implement one or more embodiments provided herein. The computing device 702 may access the computing device 720 and download a part or all of the computer readable instructions for execution. Alternatively, the computing device 702 may download pieces of the computer readable instructions, as needed, or some instructions may be executed at the computing device 702 and some at computing device 720.

### E. USAGE OF TERMS

As used in this application, the terms “component,” “module,” “system”, “interface”, and the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Furthermore, the claimed subject matter may be implemented as a method, apparatus, or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device, carrier, or media. Of course, those skilled in the art will recognize many modifications may be made to this configuration without departing from the scope or spirit of the claimed subject matter.

Various operations of embodiments are provided herein. In one embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A tray insertable into a slot of a chassis storing a multi-blade computational unit, the chassis comprising a chassis power connector and a chassis network connector, the tray comprising:
a tray base configured to support at least one blade component of a blade;
a tray power connector configured to couple with at least one blade component of the blade, and positioned to, upon insertion of a tray into a slot of the chassis, couple directly with a chassis power connector of the chassis;
a tray network connector configured to couple with a blade network connector of the blade, and positioned to, upon insertion of the tray into a slot of the chassis, couple directly with a chassis network connector of the chassis; and
a tray guide configured to couple with a chassis guide of the chassis and, upon insertion of the tray into a slot of the chassis, guide the insertion of the tray to couple the tray power connector directly with the chassis power connector and the tray network connector directly with the chassis network connector.

2. The tray of claim 1:
the tray apportioned into at least two tray blade regions respectively storing the blade components of a blade; and
the tray comprising, for respective tray blade regions:
a tray power connector configured to couple with at least one blade component of the blade in the tray blade region, and positioned to, upon insertion of the tray into a slot of the chassis, couple directly with a chassis power connector of the chassis; and
a tray network connector configured to couple with a blade network connector of the blade in the tray blade region, and positioned to, upon insertion of the tray into a slot of the chassis, couple directly with a chassis network connector of the chassis.

3. The tray of claim 1, comprising: a tray unified connector comprising the tray power connector and the tray network connector and configured to couple with a chassis unified connector comprising the chassis power connector and the chassis network connector.

4. The tray of claim 1, the tray storing blade components of blade type selected from a blade type set comprising:
a processing blade type comprising components of a processing unit at least one processing component and omitting nonvolatile storage components;
a storage blade type comprising components of a storage unit at least one nonvolatile storage component and omitting processing components;
a mixed blade type comprising at least one processing component coupled with at least one nonvolatile storage component;
a network switch blade type comprising at least one network switch component configured to couple with the network connectors of at least two other blades to provide network switching;
a chassis management blade type configured to manage other blades of the multi-blade computational unit; and
an empty blade type comprising at least one airflow block component.

5. The tray of claim 1:
the tray base configured to support a storage array comprising at least two storage components respectively composing a storage component connector; and
the tray comprising: a storage interconnect comprising:
at least two storage interconnect connectors configured to couple with the storage component connector of a storage component; and
a storage array connector configured to present the storage components of the storage component array.

6. The tray of claim 5:
the tray base configured to support at least one processing component having a processing component connector; and
the storage interconnect configured to couple with the processing component connector to present the storage components to the processing component.

7. The tray of claim 1, comprising: a tray management interface connector configured to couple with a blade management interface connector of at least one blade component of the blade, and positioned to, upon insertion of the tray into the slot of the chassis, couple with a chassis management interface connector of the chassis.

8. A chassis configured to store blades of a multi-blade computational unit, the chassis comprising:
at least one chassis power source connector configured to provide power from a chassis power source;
at least one chassis network source connector configured to provide network connectivity with a network; and
at least two substantially parallel slots respectively configured to host a tray storing at least one blade, respective slots comprising:
a chassis power connector configured to receive power from a chassis power source connector and positioned to, upon insertion of a tray into the slot, couple directly with a tray power connector of the tray;
a chassis network connector configured to communicate with the chassis network source connector and positioned to, upon insertion of the tray into the slot, couple directly with a tray network connector of the tray; and
a chassis guide configured to couple with a tray guide of the tray and, upon insertion of the tray into the slot, guide the insertion of the tray to couple the chassis power connector directly with the tray power connector and the chassis network connector directly with the tray network connector.

9. The chassis of claim 8, comprising: a chassis mount connector configured to couple with a rack mount connector of a rack configured to store at least two chassis.

10. The chassis of claim 8:
respective trays apportioned into at least two tray blade regions respectively storing the blade components of a blade, respective tray blade regions comprising a tray power connector and a tray network connector; and
respective slots comprising, for respective tray blade regions of a tray blade inserted into the slot:
a chassis power connector configured to receive power from a chassis power source connector and positioned to, upon insertion of the tray into the slot, couple directly with a tray power connector of the tray blade region of the tray; and
a chassis network connector configured to communicate with the chassis network source connector and positioned to, upon insertion of the tray into the slot, couple directly with a tray network connector of the tray blade region of the tray.

11. The chassis of claim 8, comprising: a chassis unified connector comprising the chassis power connector and the chassis network connector and configured to couple with a tray unified connector of array, the tray unified connector comprising the tray power connector and the tray network connector of a tray.

12. The chassis of claim 8:
the chassis power source comprising: at least two chassis power supplies; and
the chassis power source connector comprising, for respective chassis power supplies, a chassis power supply connector and positioned to, upon insertion of the tray into the slot, couple directly with a tray power connector of the tray.

13. The chassis of claim 12, the chassis power source connector configured to, for respective tray power connectors, couple directly with the tray power connector with one power connector selected from at least two power supplies.

14. The chassis of claim 8, comprising: at least one chassis climate regulating component embedded in the chassis and not supported by a tray, and configured to regulate climate for the blades of the chassis.

15. The chassis of claim 8, comprising: at least one network switch embedded in the chassis and not supported by a tray, and configured to couple with the tray network connectors of at least two blades to provide network switching.

16. The chassis of claim 8, comprising:
a chassis management component configured to manage the blades of the multi-blade computational unit; and
for respective slots, at least one tray management interface connector configured to couple with the chassis management component, and positioned to, upon insertion of the tray into the slot of the chassis, couple with a tray management interface connector of the tray.

17. The chassis of claim 16, the chassis management component comprising a processing component embedded in the chassis and not supported by a tray.

18. The chassis of claim 16:
the chassis power source comprising a chassis power source management interface connector; and
the chassis management component comprising a chassis power management component connector configured to couple with the chassis power source management interface connector.

19. The chassis of claim 16:
the chassis comprising at least one chassis climate regulating component comprising a chassis climate regulating component management interface connector; and
the chassis management component comprising a chassis climate regulating management component connector configured to couple with the chassis climate regulating component management interface connector.

20. A chassis system supporting a multi-blade computational unit, comprising:
a set of trays respectively comprising:
at least one tray guide;
a tray base apportioned into at least two tray blade regions respectively storing at least one blade component comprising a blade;
a tray management interface connector configured to couple with a blade management interface connector of at least one blade component of the blade; and
for respective blades of the tray:
a tray unified connector comprising a tray power connector and a tray network connector; and
for blades comprising at least two storage components respectively comprising a storage component connector, a storage interconnect comprising:
at least two storage interconnect connectors configured to couple with the storage component connector of a storage component; and
a storage array connector configured to present the storage components of the storage component array; and
a chassis mountable within a rack and providing at least two substantially parallel slots respectively configured to host a tray storing at least one blade, the chassis comprising:
a chassis mount connector configured to couple with a rack mount connector of the rack;
at least one chassis power source connector comprising at least two chassis power supplies, the chassis power source connector configured to, for respective blades, provide power from a chassis power supply selected from at least two chassis power supplies;
at least one chassis network source connector configured to provide network connectivity with a network;
for respective slots configured to receive a tray comprising a tray unified connector and at least one tray guide:
for respective blades of the tray, a chassis unified connector positioned to, upon insertion of a tray into the slot, couple directly with the tray unified connector of a blade of the tray, the chassis unified connector comprising:
a chassis power connector configured to couple the tray power connector with one power connector selected from at least two power supplies, and
a chassis network connector configured to communicate with the chassis network source connector; and
at least one chassis guide configured to, upon insertion of the tray into the slot, couple directly with a tray guide of the tray to guide the insertion of the tray to couple the chassis unified connector directly with the tray unified connector;
at least one chassis climate regulating component embedded in the chassis and not supported by a tray and configured to regulate climate for the blades of the chassis, and comprising a chassis climate regulating component management interface connector; and
at least one network switch embedded in the chassis and not supported by a tray, and configured to couple with the tray network connectors of at least two blades to provide network switching; and
a chassis management component embedded in the chassis and not supported by a tray, the chassis management component comprising:
for respective slots, at least one tray management interface connector positioned to, upon insertion of the tray into a slot of the chassis, couple with a tray management interface connector of the tray configured to manage at least one blade of the tray;
a chassis power management component connector configured to couple with the chassis power source management interface connector; and
a chassis climate regulating component management connector configured to couple with the chassis climate regulating component management interface connector.
